(19) United States
(12) Patent Application Publication
(10) Pub. No.: US 2017/0092594 A1
(43) Pub. Date: Mar. 30, 2017

(54) LOW PROFILE PACKAGE WITH PASSIVE DEVICE

(71) Applicant: QUALCOMM Incorporated, San Diego, CA (US)

(72) Inventors: Young Kyu SONG, San Diego, CA (US); Jong-Hoon LEE, San Diego, CA (US); Uei-Ming JOW, Cupertino, CA (US)

(21) Appl. No.: 14/865,749

(22) Filed: Sep. 25, 2015

(51) Int. Cl. H01L 23/552; H01L 25/00; H01L 25/065; H01L 23/498; H01L 21/48

(52) U.S. Cl. CPC H01L 23/552; H01L 23/49838; H01L 23/498; H01L 21/4846; H01L 21/4853; H01L 25/065; H01L 25/50

(57) ABSTRACT

Provided is a low-profile package and related techniques for use and fabrication. In an example, a low-profile package is provided. The low-profile package includes an exemplary integrated circuit (IC) having an active face, an integrated passive device (IPD) having a face, and a redistribution layer (RDL) disposed between the IPD and the IC. The IC is embedded in a substrate. The active face of the IC faces the face of the IPD in a face-to-face (F2F) configuration. At least one contact of the IPD is arranged in an overlapping configuration relative to the IC. The RDL is configured to electrically couple the IPD with the IC. The RDL can be disposed between the IPD and the IC, can be embedded in the substrate, and can be configured as an electromagnetic shield.

### INTRODUCTION

This disclosure relates generally to electronics, and more specifically, but not exclusively, to methods, and apparatuses relating to a low-profile package with a passive device.

There is unrelenting market demand for circuits that are smaller in size, use less power, generate less heat, are faster, have a reduced number of integrated circuit layers, are cheaper to fabricate, have higher fabrication yields, and have a reduced bill of materials, when compared to conventional devices. Few circuit elements, including radio frequency circuits, are left untouched by these ever-present market requirements.

Modern consumer devices such as mobile phones (e.g., smart phones, smart watches, etc.), computers (e.g., tablet computers, laptop computers, etc.), and navigation devices (e.g., GPS receivers, GLONASS receivers, etc.) communicate wirelessly, and thus include radio frequency (RF) circuitry. The radio frequency circuit in a device often is composed of passive components. The passive components can include capacitors, inductors, transformers, coils, and resistors. Due to constraints such as passive component size and integrated circuit fabrication process limitations, some passive components are not able to be integrated on-die (e.g., on an integrated circuit) with the RF circuit. Thus, when fabricating the RF circuit, the passive components are physically located external to the die at a significant distance from the die, and are electrically coupled to the die. Conventional techniques include mounting an integrated circuit package including the die on a printed circuit board (PCB), mounting the passive components on the PCB, and electrically coupling the die to the passive components with metal traces.

Fabricating the RF circuit with passive components located at a significant distance from the die can cause problems. One problem is crosstalk—RF signal leakage being unintentionally injected from the conductors coupling the die with the passive components to other conductors in the RF circuit and beyond. Thus, there are industry needs to provide high isolation RF shielding, minimize (i.e., reduce) RF specification degradation, and provide a need for a highly isolated ground layer. Fabricating the RF circuit with passive components located at the significant distance from the die also greatly increases an RF circuit package size and increases the number of items on the RF circuit's bill of materials.

While many conventional circuit techniques are functional, market pressure demands improvement of conventional techniques. Accordingly, there are previously unaddressed and long-felt industry needs for methods and apparatus that improve upon conventional methods and apparatus, including the provided improved methods and improved apparatus.

### SUMMARY

This summary provides a basic understanding of some aspects of the present teachings. This summary is not exhaustive in detail, and is neither intended to identify all critical features, nor intended to limit the scope of the claims.

Exemplary methods and apparatus relating to a low-profile package with a passive device are provided.

In an example, an apparatus is provided. The apparatus includes an integrated circuit having an active face. The integrated circuit is embedded in a substrate. The apparatus also includes an integrated passive device (IPD) having a face. The active face of the integrated circuit faces the face of the IPD. At least one contact of the IPD is arranged in an overlapping configuration relative to the integrated circuit. The apparatus also has a redistribution layer (RDL) disposed between the IPD and the integrated circuit. The RDL is configured to electrically couple the IPD and the integrated circuit. The IPD can include a capacitor, an inductor, a transformer, a coil, or a combination thereof. The apparatus can include a second integrated circuit embedded in the substrate and an interposer disposed between the integrated circuit and the second integrated circuit. The interposer is electrically coupled to a first portion of the RDL and a second portion of the RDL. The interposer is configured to couple signals between the integrated circuit and the IPD on the first portion of the RDL and the second circuit on the second portion of the RDL. The interposer can be embedded in the substrate or mounted external to the substrate. The apparatus can include an electromagnetic shield located between the substrate and the IPD. At least a portion of a redistribution layer can be configured as the electromagnetic shield. The integrated circuit can be coupled to a land grid array formed on the substrate. The apparatus can be incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, a base station, and a device in a automotive vehicle, and further including the device.

In another example, provided is a method for fabricating a package. The method can include forming an RDL as part of a substrate, mounting an IPD on the substrate and electrically coupling the IPD to a first side of the RDL, embedding an integrated circuit in substrate in a face-to-face orientation with IPD, and electrically coupling the IPD to a second side of the RDL to electrically couple the IPD to the integrated circuit. At least one contact of the IPD is arranged in an overlapping configuration relative to the integrated circuit. At least a portion of the RDL can be configured as an electromagnetic shield. The IPD can include at least one of a capacitor, an inductor, a transformer, a coil, or a combination thereof. The method can include embedding a second integrated circuit in the substrate, embedding an interposer disposed between the integrated circuit and the second integrated circuit, and electrically coupling the interposer to a first portion of the RDL and a second portion of the RDL. The interposer is configured to couple signals between the integrated circuit and the IPD on the first portion of the RDL and the second circuit on the second portion of the RDL. The method can also include embedding a second integrated circuit in the substrate, mounting an interposer on the substrate disposed between the integrated circuit and the second integrated circuit, and electrically coupling the interposer to a first portion of the RDL and a second portion of the RDL. The interposer is configured to couple signals between the integrated circuit and the IPD on a first portion of the RDL and the second circuit on a second portion of the RDL. The method can also include forming a land grid array (LGA) on the substrate and coupling the LGA to the integrated circuit. The method can also include incorporating the package into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, a base station, and a device in a automotive vehicle, and further including the device.

In another example, another apparatus is provided. The apparatus includes an integrated circuit having an active face. The integrated circuit is embedded in a substrate. The apparatus can also include a passive device having an active face. The active face of the integrated circuit faces the active face of the passive device. The apparatus also includes means for electrically coupling the passive device to the integrated circuit. The passive device can include a capacitor, an inductor, a transformer, a coil, or a combination thereof. An interposer can be embedded in the substrate. The apparatus can also include an electromagnetic shield located between the substrate and the passive device. At least a portion of a redistribution layer can be configured as the electromagnetic shield. The apparatus can also include means for electrically coupling the integrated circuit to a land grid array. The land grid array is formed on the substrate. The substrate can include a redistribution layer. The apparatus can be incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, a base station, and a device in a automotive vehicle, and further including the device.

The foregoing broadly outlines some of the features and technical advantages of the present teachings in order that the detailed description and drawings can be better understood. Additional features and advantages are also described in the detailed description. The conception and disclosed examples can be used as a basis for modifying or designing other devices for carrying out the same purposes of the present teachings. Such equivalent constructions do not depart from the technology of the teachings as set forth in the claims. The inventive features that are characteristic of the teachings, together with further objects and advantages, are better understood from the detailed description and the accompanying figures. Each of the figures is provided for the purpose of illustration and description only, and does not limit the present teachings.

### BRIEF DESCRIPTION OF THE DRAWINGS

The accompanying drawings are presented to describe examples of the present teachings, and are not limiting.

FIG. 1 depicts an exemplary low-profile package with an integrated passive device.

FIG. 2 depicts another exemplary low-profile package with an integrated passive device.

FIGS. 3A-E depict exemplary radio frequency isolation test results.

FIG. 4 depicts an exemplary method for fabricating a low-profile package with an integrated passive device.

FIGS. 5A-C depict another exemplary method for fabricating a low-profile package with an integrated passive device.

FIG. 6 illustrates various electronic devices that may include a low-profile package with an integrated passive device.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Provided are methods and apparatus that generally relate to electronics, and more specifically, but not exclusively, to a low-profile package with an integrated passive device. Examples provided include a low-profile radio frequency (RF) integrated circuits (ICs) having an integrated passive device and an embedded interposer or a flip-chip (FC) interposer configuration.

Face-to-face (F2F) is a three-dimensional (3-D) technique for combining multiple integrated circuit chips (e.g., dies) in a stacked manner that can have high-density (and thus high-bandwidth) coupling between multiple integrated circuit chips. The stacking forms multi-layered devices. The high-density coupling can be through matching vertical vias on each of the stacked chips, electrically coupling the stacked chips via a redistribution layer, electrically coupling the stacked chips via metallic wires, mating electrical interconnects, or a combination thereof. In examples, the electrical interconnects can be pillars, copper pillars, solder balls, solder pads, wire bonds, pads, contacts, the like, or a combination thereof. These electrical interconnects allow components to be electrically coupled in the F2F configuration.

The exemplary apparatuses and exemplary methods disclosed herein advantageously addresses the long-felt industry needs, as well as other previously unidentified needs, and mitigate shortcomings of the conventional methods and the conventional apparatus. For example, among other advantages, when compared to conventional techniques, the techniques disclosed herein can advantageously reduce power consumption, provide a reduced bill of material (BOM), provide lower fabrication costs, provide high isolation RF shielding, reduce RF specification degradation, reduce package size, mitigate a need for a highly isolated ground layer, reduce heat generation, and combinations thereof.

Examples are disclosed in this application's text and drawings. Alternate examples can be devised without departing from the scope of the disclosure. Additionally, conventional elements of the current teachings may not be described in detail, or may be omitted, to avoid obscuring aspects of the current teachings.

Spatial descriptions (e.g., “top,” “middle,” “bottom,” “left,” “center,” “right,” “up,” “down,” “vertical,” “horizontal,” etc.) used herein are for illustrative purposes only, and are not limiting descriptors. Practical implementations of the structures described hereby can be spatially arranged in any orientation providing the functions described hereby. In addition, in using the term “adjacent” herein to describe a spatial relationship between integrated circuit elements, the adjacent integrated circuit elements need not be in direct physical contact, and other integrated circuit elements can be located between the adjacent integrated circuit elements.

As used herein, the term “exemplary” means “serving as an example, instance, or illustration.” Any example described as “exemplary” is not necessarily to be construed as preferred or advantageous over other examples. Likewise, the term “examples” does not require that all examples include the discussed feature, advantage, or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

It should be noted that the terms “connected,” “coupled,” and any variant thereof, mean any connection or coupling between elements, either direct or indirect, and can encompass a presence of an intermediate element between two elements that are “connected” or “coupled” together via the intermediate element. Coupling and connection between the elements can be physical, logical, or a combination thereof. Elements can be “connected” or “coupled” together, for example, by using one or more wires, cables, printed electrical connections, electromagnetic energy, and the like. The electromagnetic energy can have a wavelength at a radio frequency, a microwave frequency, a visible optical frequency, an invisible optical frequency, and the like, as practicable. These are several non-limiting and non-exhaustive examples.

The term “signal” can include any signal such as a data signal, an audio signal, a video signal, a multimedia signal, an analog signal, a digital signal, and the like. Information and signals described herein can be represented using any of a variety of different technologies and techniques. For example, data, an instruction, a process step, a process block, a command, information, a signal, a bit, a symbol, and the like that are references herein can be represented by a voltage, a current, an electromagnetic wave, a magnetic field, a magnetic particle, an optical field, and optical particle, and/or any practical combination thereof, depending at least in part on the particular application, at least in part on the desired design, at least in part on the corresponding technology, and/or at least in part on like factors.

A reference using a designation such as “first,” “second,” and so forth does not limit either the quantity or the order of those elements. Rather, these designations are used as a convenient method of distinguishing between two or more elements or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” or “one or more of A, B, or C” or “at least one of the group consisting of A, B, and C” used in the description or the claims can be interpreted as “A or B or C or any combination of these elements.” For example, this terminology can include A, or B, or C, or (A and B), or (A and C), or (B and C), or (A and B and C), or 2A, or 2B, or 2C, and so on.

The terminology used herein is for the purpose of describing particular examples only and is not intended to be limiting. As used herein, the singular forms “a,” “an,” and “the” include the plural forms as well, unless the context clearly indicates otherwise. In other words, the singular portends the plural, where practicable. Further, the terms “comprises,” “comprising,” “includes,” and “including,” specify a presence of a feature, an integer, a step, a block, an operation, an element, a component, and the like, but do not necessarily preclude a presence or an addition of another feature, integer, step, block, operation, element, component, and the like.

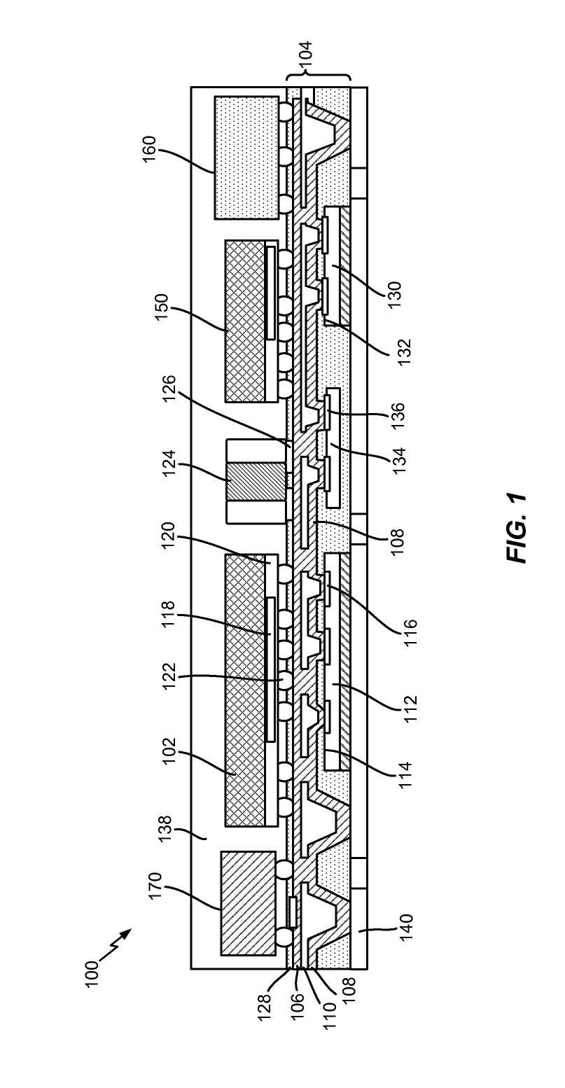

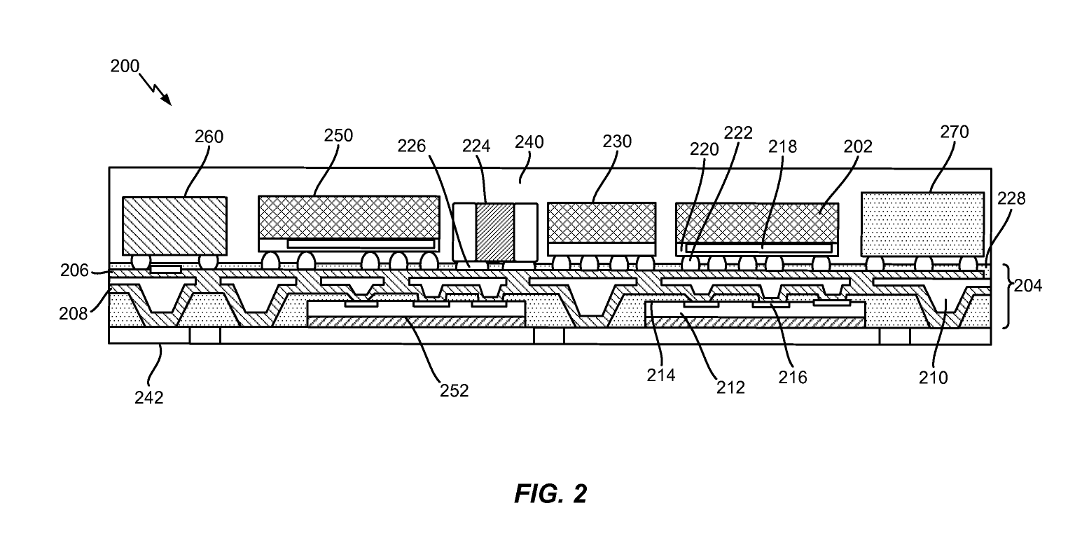

In at least one example, the provided apparatuses in FIGS. 1-2 can be a part of, and/or coupled to, an electronic device such as, but not limited to, at least one of: a mobile device, a navigation device (e.g., a global positioning system receiver), a wireless device, a camera, an audio player, a camcorder, a computer, and a game console. The term “mobile device” can describe, and is not limited to: a mobile phone, a mobile communication device, a pager, a personal digital assistant, a personal information manager, a personal data assistant, a mobile hand-held computer, a portable computer, a tablet computer, a wireless device, a wireless modem, other types of portable electronic devices typically carried by a person and having communication capabilities (e.g., wireless, cellular, infrared, short-range radio, etc.), the like, or a combination thereof. Further, the terms “user equipment” (UE), “mobile terminal,” “user device,” “mobile device,” and “wireless device” can be interchangeable.

FIG. 1 depicts an exemplary IC Package 100 having an integrated passive device 102. The IC Package 100 includes a substrate 104 which may include a core, or may be a coreless substrate. The substrate 104 may include a first metal layer 106 and a second metal layer 108, separated by a dielectric material 110. The first metal layer 106 and second metal layer 108 may function to redistribute signals (e.g. signals, power, ground) to and from IC devices with different input/output pitches. In an example, the substrate 104 has only two metal layers. However, the substrate may have more than two metal layers. The first metal layer 106 and the second metal layer 108 may function as a redistribution layer (RDL) (i.e., a means for electrically coupling). At least one of the first metal layer 106 and the second metal layer 108 may also function at least partially as radio frequency (RF) shielding (i.e., a means for shielding). The thicknesses depicted in FIG. 1 are exemplary and are not limiting.

Reducing a number of metal layers in the substrate 104 advantageously reduces an overall height of the IC Package 100. Having only two metal layers reduces a “z” height (i.e., a package thickness of the IC Package 100), and enables functional RF applications of the IC Package 100.

A first integrated circuit (IC) 112 (e.g., a memory die, an RF die, a processor, the like, or a combination thereof) may be embedded in the substrate 104. The first IC 112 has an active face 114. The active face 114 of the first IC 112 is coupled to the second metal layer 108 with an electrical interconnect 116 (i.e., means for electrically coupling such as pillars, copper pillars, solder balls, solder pads, wire bonds, pads, contacts, the like, or a combination thereof).

The IC Package 100 has a smaller size because the first IC 112 can be smaller due to the passive device 102 being external to the first IC 112 and substrate 104. The configuration of the IC Package 100 enables placing the passive device 102 at a location external to the first IC 112 and the substrate 104. Thus, the first IC 112 need not have the passive device 102 integrated in the first IC 112 and/or substrate 104, which reduces the requirements for metal layers, keep-out zones, and RF shielding. In a non-limiting example, the reduction in metal layers allows the substrate 104 to have a thickness (e.g., in a “z” direction) of approximately 150 um, instead of approximately 298 um for the conventional substrates.

In an example, the integrated passive device 102 may include a coil 118. The coil 118 can be embedded in an integrated passive device routing region 120. In an example, the integrated passive device routing region 120 can be formed from a mechanical wafer or a glass wafer. The integrated passive device 102 can be electrically coupled to the first metal layer 106 with an electrical interconnect 122 (i.e., means for electrically coupling such as pillars, copper pillars, solder balls, solder pads, wire bonds, pads, contacts, the like, or a combination thereof). Alternatively, the integrated passive device 102 may be wire bonded to the first metal layer 106 (not shown). The IC Package 100 may also include a surface mount device (SMD) 124. At least one of the integrated passive device 102 or the SMD 124 may include a capacitor, an inductor, a transformer, a coil, the like, or a combination thereof. The SMD 124 has an electrical interconnect 126 (i.e., means for electrically coupling such as pillars, copper pillars, solder balls, solder pads, wire bonds, pads, contacts, the like, or a combination thereof), which couples the SMD 124 to the first metal layer 106.

At least one of the integrated passive device 102 or the SMD 124 may be integrated into a low-cost flip chip. In an example, at least one of the integrated passive device 102 or the SMD 124 may be located at least partially over the first IC 112. For example, as illustrated in FIG. 1, the integrated passive device 102 can be located over a surface 128 of the substrate 104, in a F2F orientation with the active face 114 of the first IC 112, in which the integrated passive device 102 and the first IC 112 at least partially overlap. The overlap of the first IC 112 and the integrated passive device 102 allows for the electrical interconnect 122 of the integrated passive device 102 to be positioned over the first IC 112. In one example, the overlap includes at least five electrical interconnects. In another example, the SMD 124 can be located over the surface 128 of the substrate 104, in a F2F orientation with the first IC 112, in which the SMD 124 and the first IC 112 overlap. In an example, the overlap of the first IC 112 and the SMD 124 is for at least one electrical interconnect.

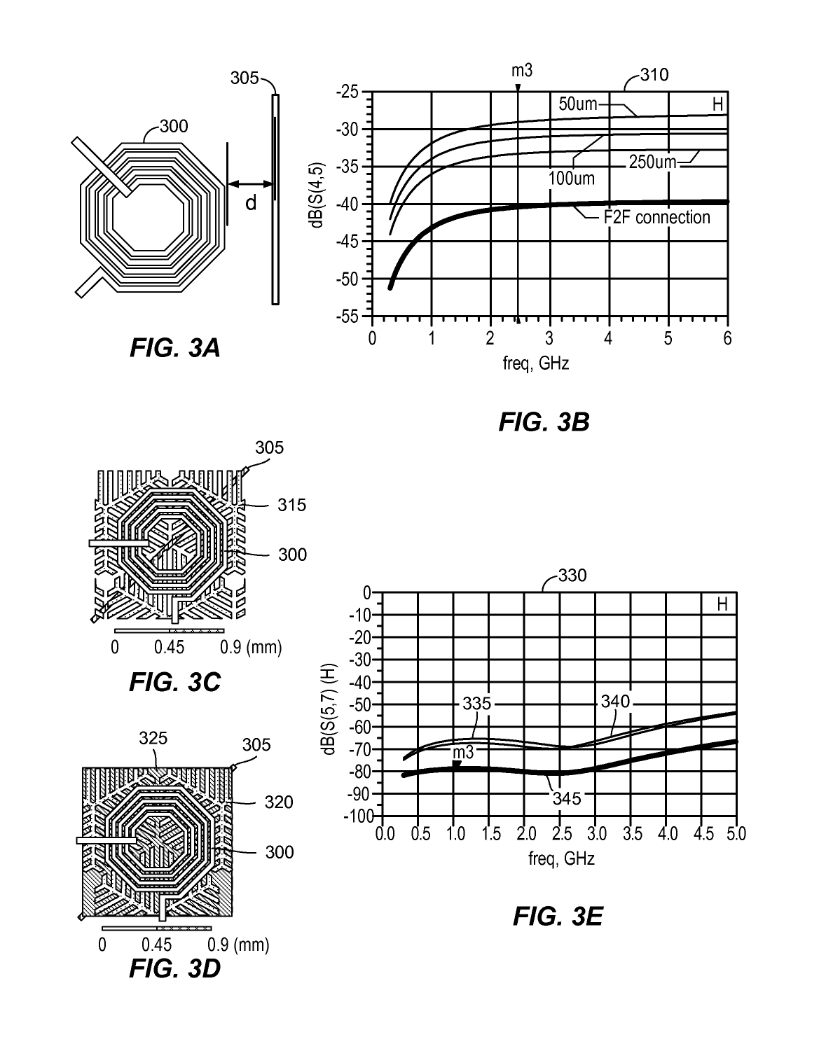

The unique geometry and configuration of the IC package 100 advantageously provides RF isolation, while at the same time reducing a “z” height of the IC package 100. The electrical interconnect 122 (e.g., configured as a solder ball as illustrated) provides additional separation between the substrate 104 and the first IC 112 (e.g., height “d” in FIG. 3A) to provide improved RF isolation between the integrated passive device 102 and the first IC 112. Accordingly, the IC package 100 need not otherwise be thicker to provide the RF isolation. The unique geometry and configuration of the IC package 100 can also relax spacing considerations between components (e.g., an L/S substrate design rule).

The IC package 100 can also advantageously reduce fabrication costs. In the IC package 100, electromagnetic components are migrated out of an integrated circuit chip and into the integrated passive device 102. Fabricating the integrated passive device 102 as a device that is outside of an integrated circuit chip is less expensive than integrating the integrated passive device 102 inside of an integrated circuit chip. Therefore, the IC Package 100 has a lower overall fabrication cost because fabricating the integrated passive device 102 as a separate device is less expensive than integrating the integrated passive device 102 in the first IC 112.

Further, the IC package's 100 size is smaller because the configuration and geometry of the IC package 100 avoids using long traces between the integrated passive device 102 and the first IC 112. Instead of a long trace, the F2F configuration in the IC package 100 uses shorter connections by positioning the integrated passive device 102 at least partially overlapping the first IC 112, as discussed above. Also, configuring the IC package 100 with the integrated passive device 102 external to the first IC 112 advantageously reduces RF specification degradation and electromagnetic effects due to crosstalk with printed circuit board (PCB) conductors, when the IC package 100 is mounted on a PCB.

The integrated passive device 102 may have thicker metal conductors (when compared to conventional devices), which improves electrical performance of the integrated passive device 102. Being able to fabricate the integrated passive device 102 with the thicker metal conductors can improve the quality factor of the passive devices (e.g., an inductor, the coil 118, etc.) within the integrated passive device 102. In one example, when the integrated passive device 102 is an inductor, a coil of the integrated passive device 102 (e.g., the coil 118) can be thicker (up to 37 μm thickness) when using a glass substrate (or a mechanical substrate) versus a die (8-9 μm thickness). For example, the thicker metal of the coil of the integrated passive device 102 provides lower resistance of the coil, which improves the quality factor of the inductor. Using a high-quality passive device (e.g., a choke inductor) may also advantageously reduce power consumption. Further, the unique geometry and configuration of the IC package 100 advantageously enables using a low-cost fabrication process for the integrated passive device 102, because the coil does not need a high-node silicon process. A low-cost fabrication process can include fabricating the integrated passive device 102 on a glass wafer or a mechanical wafer. Further, fabricating the IC package 100 with the integrated passive device 102 is less expensive because the integrated passive device 102 can be embedded in a low cost die, rather than being embedded in an expensive die (e.g., a 16nm node die).

At least one of the first metal layer 106 or the second metal layer 108 may be configured at least partially as an electromagnetic shield to improve RF isolation, and in some examples can provide up to substantially −70 dB of electromagnetic isolation. For example, the first metal layer 106 can be configured with a ground shielding pattern (e.g., a means for shielding), which may be in a cross-hatch (see, e.g., FIG. 3, ref. 315) or any suitable pattern, between the first IC 112 and at least one of the integrated passive device 102 and the SMD 124. The ground shielding pattern acts as an RF shield to decouple a magnetic field of the integrated passive device 102 and/or a magnetic field of the SMD 124 from the first IC 112.

Configuring at least one of the first metal layer 106 or the second metal layer 108 at least partially as an electromagnetic shield reduces the bill of materials because the metal layer(s) can act both as a redistribution layer and as an electromagnetic shield, thus reducing the quantity of materials necessary to fabricate the IC package 100. The dual use of the metal layer(s) also reduces a size of the IC package 100 because the IC package 100 does not require an additional dedicated RF shielding layer.

The IC Package 100 can also include a second IC 130 (e.g., a memory die, an RF die, a processor). The second IC 130 can be configured in a split-die arrangement with the first IC 112. The second IC 130 is embedded in the substrate 104 and has an active face 132. The second IC 130 can be electrically coupled, via an RDL (e.g., the first metal layer 106 and/or the second metal layer 108), to an interposer 134 (i.e., a means for electrically coupling, such as a routing device) which is also embedded in substrate 104. The interposer 134 can be used to electrically couple between the first IC 112 and the second IC 130. Accordingly, the interposer 134 enables implementing a split-die configuration. Thus, instead of using a single IC having combined features of both ICs, the first IC 112 and the second IC 130 can be used. Since independent ICs are used, the interposer 134 can also reduce the complexity in the routing schemes in the RDL (e.g., in the first and/or second metal layers) and additional solder interconnects (e.g., solder bumps, solder pads, solder balls, etc.) that are often used in a split die configuration. In one example, the interposer 134 can be disposed between the first IC 112 and the second IC 130. The interposer can be electrically coupled to a first portion of the RDL generally associated with routing for the first IC 112 and a second portion of the RDL generally associated with routing for the second IC 112. As discussed above, the interposer 134 can be configured to couple signals between the first IC 112 and the IPD 102 and other components on the first portion of the RDL and the second IC 130 on the second portion of the RDL. The interposer 134 and split die configuration can reduce the complexity of the routing scheme, which can also advantageously reduce breakout problems and ground layer usage for high isolation in fine pitch connections.

Implementing the split-die configuration can reduce fabrication costs, as the split-die arrangement enables the IC package 100 to be fabricated with different integrated circuits and other components that each are respectively fabricated using respective processes. In a non-limiting example, the first IC 112 can be fabricated using a more expensive process (e.g., a 180 nm silicon-on-insulator process), while the second IC 130 and/or second IC 130 can be fabricated using a lower cost process (e.g., a CMOS process). Implementing the split-die configuration also enables better thermal performance by thermally coupling at least one of the first IC 112 and the second IC 130 to a PCB on which the IC package 100 is mounted. The thermal coupling dissipates heat from the first IC 112, the second IC 130, or both.

The integrated passive device 102 may be mechanically secured in place in the IC Package 100 using an encapsulant 138 such as molding, underfill, the like, or a combination thereof.

Further, the IC package 100 may include an electrical interconnect 140 (i.e., means for electrically coupling such as pillars, copper pillars, solder balls, solder pads, wire bonds, pads, contacts, a land grid array, the like, or a combination thereof) that may be electrically coupled to the first IC 112, the second IC 130, the integrated passive device 102, the SMD 124, the like, or a combination thereof, via the first metal layer 106 and/or the second metal layer 108, where the first metal layer 106 and/or second metal layer 108 may function as a redistribution layer. The electrical interconnect 140 can be used to couple the IC package 100 to a PCB.

Additional optional components are illustrated. For example, an integrated passive device 150 is illustrated, which may be arranged in a F2F configuration with the second IC 130. Surface mount devices 160 and 170 (e.g., a passive device, a SMD, an IC, the like, and combinations thereof) may also be optionally provided to support the circuit function based on a given design of IC package 100.

FIG. 2 depicts an exemplary IC Package 200 having an integrated passive device 202 and an interposer 230. In the configuration illustrated in FIG. 2, instead of an embedded interposer as illustrated in FIG. 1, the interposer 230 is mounted external to substrate 204. The integrated passive device 202 may include a capacitor, an inductor, a transformer, a coil, the like, or a combination thereof. The IC Package 200 includes a substrate 204 which may include a core, or may be a coreless substrate. The substrate 204 may include a first metal layer 206 and a second metal layer 208, separated by a dielectric material 210. The first metal layer 206 and second metal layer 208 may function to redistribute signals (e.g. signals, power, ground) to and from IC devices with different input/output pitches. In an example, the substrate 204 has only two metal layers. At least one of the first metal layer 206 and the second metal layer 208 may function as a redistribution layer (RDL). At least one of the first metal layer 206 and the second metal layer 208 may function as radio frequency (RF) shielding (i.e., a means for shielding). The thicknesses depicted in FIG. 2 are exemplary and are not limiting.

Reducing a number of metal layers in the substrate 204 advantageously reduces an overall height of the IC Package 200. Having only two metal layers reduces a “z” height (i.e., a package thickness of the IC Package 200), and enables functional RF applications of the IC Package 200, as discussed above in relation to FIG. 1.

A first integrated circuit (IC) 212 (e.g., a memory die, an RF die, a processor) may be embedded in the substrate 204. The first IC 212 has an active face 214. The active face 214 of the IC 212 is coupled to the second metal layer 208 with an electrical interconnect 216 (e.g., means for electrically coupling including pillars, copper pillars, solder balls, solder pads, wire bonds, pads, contacts, the like, or a combination thereof).

The IC Package 200 has a smaller size because the first IC 212 can be smaller due to the integrated passive device 202 being external to the first IC 212. The configuration of the IC Package 200 enables placing the integrated passive device 202 at a location external to the first IC 212. Thus, the first IC 212 need not have the integrated passive device 202 integrated in the first IC 212. In a non-limiting example, the reduction in metal layers allows the substrate 204 to have a thickness (e.g., in a “z” direction) of approximately 150 μm, instead of approximately 298 μm for the conventional substrates.

In an example, the integrated passive device 202 may include a coil 218. The coil 218 can be embedded in an integrated passive device routing region 220. In an example, the integrated passive device routing region 220 can be formed from a mechanical wafer or a glass wafer. The integrated passive device 202 can be electrically coupled to the first metal layer 106 with an electrical interconnect 222 (i.e., means for electrically coupling such as pillars, copper pillars, solder balls, solder pads, wire bonds, pads, contacts, the like, or a combination thereof). Alternatively, the integrated passive device 202 may be wire bonded to the first metal layer 206 (not shown). The IC Package 200 may also include a surface mount device (SMD) 224. At least one of the integrated passive device 202 or the SMD 224 may include a capacitor, an inductor, a transformer, a coil, the like, or a combination thereof. The SMD 224 has an electrical interconnect 226 (i.e., means for electrically coupling such as pillars, copper pillars, solder balls, solder pads, wire bonds, pads, contacts, the like, or a combination thereof), which couples the SMD 224 to the first metal layer 206.

At least one of the integrated passive device 202 or the SMD 224 may be located at least partially over the first IC 212. For example, the integrated passive device 202 can be located over a surface 228 of the substrate 204, in a F2F orientation with the active face 214 of the first IC 212, in which the integrated passive device 202 and the first IC 212 overlap. In an example, the overlap of the first IC 212 and the integrated passive device 202 is for at least one electrical interconnect. In another example, the overlap is for at least five electrical interconnects. In another example, the SMD 224 can be located over the surface 228 of the substrate 204, in a F2F orientation with the first IC 212, in which the SMD 224 and the first IC 212 overlap. In an example, the overlap of the first IC 212 and the SMD 224 is for at least one electrical interconnect. In another example, the overlap is for at least five electrical interconnects.

The unique geometry and configuration of the IC package 200 advantageously provides RF isolation, while at the same time reducing both a size of the IC package 200 and a profile of the IC package 200. The electrical interconnect 226 and the electrical interconnect 222 provide additional height (“d” in FIG. 3A) to provide improved RF isolation between the integrated passive device 202, the SMD 224, and the first IC 212. The unique geometry and configuration of the IC package 200 also reuses height that is already being used for the electrical interconnect 226 and the electrical interconnect 222, without adding additional height to provide the RF isolation. Thus, the IC package 200 need not otherwise be thicker to provide the RF isolation. The unique geometry and configuration of the IC package 200 can also relax, and in some cases eliminate, spacing considerations between components (e.g., the L/S substrate design rule).

The IC package 200 can also advantageously reduce fabrication costs. In the IC package 200, electromagnetic components are migrated out of an integrated circuit chip and onto the substrate 204. Fabricating the integrated passive device 202 as a device that is outside of an integrated circuit chip is less expensive than integrating the integrated passive device 202 inside of an integrated circuit chip. Therefore, the IC Package 200 has a lower overall fabrication cost because fabricating the integrated passive device 202 as a separate device is less expensive than integrating the integrated passive device 202 in the first IC 212.

Further, the IC package's 200 size is smaller because the configuration and geometry of the IC package 200 avoids using long traces between the integrated passive device 202 and the first IC 212. Instead of a long trace, the IC package 200 uses shorter connections—the electrical interconnect 226 and the electrical interconnect 222. Also, configuring the IC package 200 with the integrated passive device 202 external to the first IC 212 advantageously reduces RF specification degradation and electromagnetic effects due to crosstalk with PCB conductors, when the IC package 200 is mounted on a PCB.

The unique geometry and configuration of the IC package 200 also advantageously enables using an integrated passive device 202 that has thicker metal conductors (when compared to conventional devices), which improves electrical performance of the integrated passive device 202. Being able to fabricate the integrated passive device 202 with the thicker metal conductors increases the quality of the integrated passive device 202 when the integrated passive device 202 is an inductor. Thus, the unique geometry and configuration of the IC package 200 advantageously enables using high-quality passive components. Thus, when the integrated passive device 202 is an inductor, a coil (e.g., the coil 218) of the integrated passive device 202 can be thicker (up to 37 μm thickness) when using a glass substrate (or a mechanical substrate) versus a die (8-9 μm thickness). The thicker metal of the coil provides lower resistance of the coil, which improves the inductance and the quality factor of the coil. Using a high-quality passive device (e.g., a choke inductor) may also advantageously reduce power consumption. Further, the unique geometry and configuration of the IC package 200 advantageously enables using a low-cost fabrication process, such as a fabrication process using a glass substrate or mechanical substrate, for the integrated passive device 202, because the coil does not need a high-node silicon process. A low-cost fabrication process can include fabricating the integrated passive device 202 on a glass wafer or a mechanical wafer. Further, fabricating the IC package 200 with the integrated passive device 202 is less expensive because the integrated passive device 202 can be embedded in a low cost die, rather than being embedded in an expensive die (e.g., a 16 nm node die).

At least one of the first metal layer 206 or the second metal layer 208 may be configured at least partially as an electromagnetic shield to improve RF isolation, and in some examples can provide up to substantially −70 dB of electromagnetic isolation. For example, the first metal layer 206 can be configured with a ground shielding pattern (e.g., a means for shielding), which may be in a cross-hatch (see, e.g., FIG. 3, ref. 315) or any suitable pattern, between the first IC 212 and at least one of the integrated passive device 202 and the SMD 224. The ground shielding pattern acts as an RF shield to decouple a magnetic field of the integrated passive device 102 and/or a magnetic field of the SMD 124 from the first IC 212. The ground shielding pattern can also act as an RF shield to decouple a magnetic field of conductors and other components on the PCB from the integrated passive device 202.

Configuring at least one of the first metal layer 206 or the second metal layer 208 at least partially as an electromagnetic shield also reduces the bill of materials because the metal layer(s) may function a redistribution layer and as an electromagnetic shield, thus reducing the quantity of materials necessary to fabricate the IC package 200. The dual use of the metal layer(s) also reduces a size of the IC package 200 because the IC package 200 does not require an additional dedicated RF shielding layer.

The IC Package 200 can also include interposer 230, as noted above. The interposer 230 can be used to electrically couple signals between a first portion of the RDL (e.g., metal layers 206 and 208) associated with the first IC 212 and a second portion of the RDL associated with a second IC 252. As discussed above, in relation to FIG. 1, the interposer 230 provides similar functionality as interposer 134 and can facilitate the split die configuration which can reduce the complexity of the routing scheme for the IC package 200.

The integrated passive device 202 may be mechanically secured in place in the IC Package 200 using an encapsulant 240 such as molding, underfill, the like, or a combination thereof.

Further, the IC package 200 may include a electrical interconnect 242 (i.e., means for electrically coupling such as pillars, copper pillars, solder balls, solder pads, wire bonds, pads, contacts, the like, or a combination thereof) that may be electrically coupled to the first IC 212, the integrated passive device 202, the SMD 224, or a combination thereof, via the first metal layer 206 and/or the second metal layer 208, where the first metal layer 206 and/or second metal layer 208 may function as a redistribution layer. The electrical interconnect 242 can be used to couple the IC package 200 to a PCB.

Additional optional components are illustrated. For example, an integrated passive device 250 is illustrated, which may be arranged in a F2F configuration with the second IC 252. Surface mount devices 260 and 270 (e.g., a passive device, a SMD, an IC, the like, and combinations thereof) may also be optionally provided to support the circuit function based on a given design of IC package 200.

FIGS. 3A-E depict inductors and associated exemplary radio frequency isolation test results. The patterns depicted in FIGS. 3A, 3C, and 3D are non-limiting examples—other practicable patterns can be implemented.

FIG. 3A depicts an inductor 300 (e.g., the coil 118, the coil 218, the like, or a combination thereof) and a conductor 305 that are separated by a distance “d”. The distance “d” can be the distance between a passive device (e.g. 102, 202, 224) and an IC (e.g., 112, 130, 212). The distance “d” can be a portion of the distance between a passive device (e.g. 102, 202, 224) and a metal layer (e.g., 106, 108). The distance “d” can be obtained at least in part by way of the heights of the electrical interconnect 122, the electrical interconnect 222, the like, or a combination thereof. For example, the electrical interconnect 122, the electrical interconnect 222, the like, or the combination thereof are present due to implementing the F2F configuration of the passive device (e.g. 102, 202, 224) and the IC (e.g., 112, 130, 212).

FIG. 3B depicts exemplary test results 310 indicating a quantity of magnetic flux leakage at different distances “d” over a range of frequencies. The test results 310 in FIG. 3B indicate that separating the passive device (e.g. 102, 202, 224) with interconnects and shielding results in less magnetic flux leakage for a given frequency. For example, for a given frequency m3, the magnetic flux leakage is approximately −40 dbm when “d” is greater than 250 um, in contrast with the higher magnetic flux leakage for d=50 um, 100 um, 250 um. In other words, in the examples described in this document including FIGS. 1-2, the distance “d” between the passive device (e.g. 102, 202, 224) and the IC (e.g. 112, 130, 212) is greater than 250 um, thereby resulting in higher isolation and less magnetic flux leakage. A larger “d,” and thus the reduced magnetic flux leakage, is obtained by using the already existing “z” height of the electrical interconnects, without further increasing the overall package size. This is contrasted with traditional techniques of integrating the passive device on-chip, which leads to more flux leakage. Furthermore, the distance “d” also separates the passive device (e.g. 102, 202, 224) from a PCB upon which the IC package (e.g., 100, 200) is mounted, thus reducing flux leakage between the passive device (e.g. 102, 202, 224) and the PCB. The test results 310 thus indicate that the provided techniques result in less magnetic flux leakage.

FIG. 3C depicts the inductor 300 (e.g., the coil 118, the coil 218), the conductor 305, and a single ground plane 315 located between the inductor 300 and the conductor 305. The single ground plane 315 can be a part of the first metal layer 106, the second metal layer 108, the first metal layer 206, or the second metal layer 208. The single ground plane 315 can be a patterned ground, which can be configured with a pattern that provides more isolation at specific frequencies.

FIG. 3D depicts the inductor 300 (e.g., the coil 118, the coil 218), the conductor 305, a first ground plane 320 located between the inductor 300 and the conductor 305, as well as a second ground plane 325 located between the inductor 300 and the conductor 305. The first ground plane 320 can be a part of the first metal layer 106, the second metal layer 108, the first metal layer 206, or the second metal layer 208. The first ground plane 320 can be a patterned ground, which can be configured with a pattern that provides more isolation at specific frequencies. The second ground plane 325 can be a part of the first metal layer 106, the second metal layer 108, the first metal layer 206, or the second metal layer 208, where the second ground plane 325 is not a part of the same layer as the first ground plane 320. The second ground plane 325 can be a patterned ground, which can be configured with a pattern that provides more isolation at specific frequencies. Thus, FIG. 3D depicts a two-layer ground configuration.

FIG. 3E depicts exemplary test results 330 indicating a quantity of magnetic flux leakage of different shielding arrangements at a distance “d” and over a range of frequencies. A first trace 335 indicates magnetic flux leakage for a single layer ground pattern, such as that provided by the single ground plane 315. A second trace 340 indicates magnetic flux leakage for a two-layer layer ground pattern, such as that provided by the first ground plane 320 in combination with the second ground plane 325. The second trace 340 shows that the two-layer ground pattern yields an improvement in isolation, over the single layer ground pattern, by about 1-2 dB. A third trace 345 indicates magnetic flux leakage for a planar continuous metal shield, which yields an improvement in isolation, over the two-layer ground pattern, by about 10-12 dB.

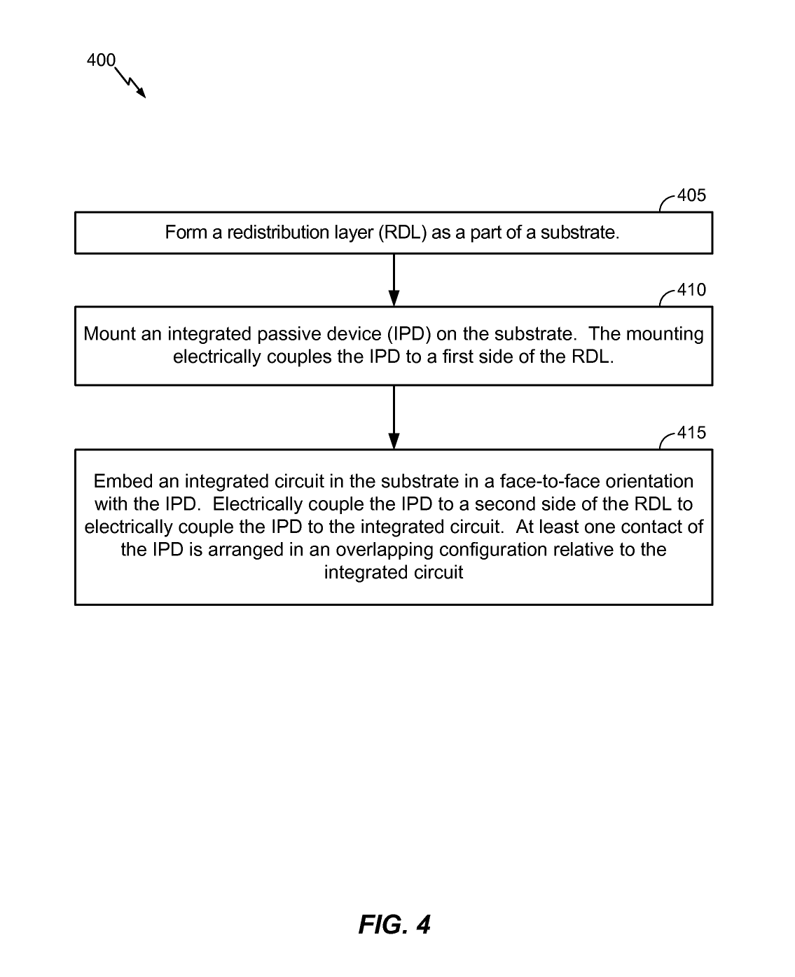

FIG. 4 depicts an exemplary method 400 for fabricating a package (e.g., an IC package including a passive device). Deposition of a material to form at least a portion of a structure described herein can be performed using deposition techniques such as physical vapor deposition (PVD, e.g., sputtering), plasma-enhanced chemical vapor deposition (PECVD), thermal chemical vapor deposition (thermal CVD), and/or spin-coating. Etching of a material to form at least a portion of a structure described herein can be performed using etching techniques such as plasma etching.

In block 405, an RDL (e.g., the first metal layer 106, the second metal layer 108, the like, or a combination thereof) is formed as part of a substrate (e.g., the substrate 104, the substrate 204, the like, or a combination thereof). At least a portion of the RDL can be configured as an electromagnetic shield.

In block 410, an IPD (e.g., the integrated passive device 102, the SMD 124, the integrated passive device 202, the SMD 224, the like, or a combination thereof) is mounted on the substrate. The IPD is electrically coupled to a first side of the RDL. The IPD can include at least one of a capacitor, an inductor, a transformer, a coil (e.g., the coil 118, the coil 218, the like, or a combination thereof), or a combination thereof.

In block 415, an integrated circuit (e.g., the first IC 112, the second IC 130, the first IC 212, the like, or a combination thereof) is embedded in the substrate in a face-to-face orientation with the IPD. The IPD is electrically coupled to a second side of the RDL to electrically couple the IPD to the integrated circuit. At least one contact of the IPD is arranged in an overlapping configuration relative to the integrated circuit.

The foregoing blocks are not limiting of the examples. The blocks can be combined and/or the order can be rearranged, as practicable.

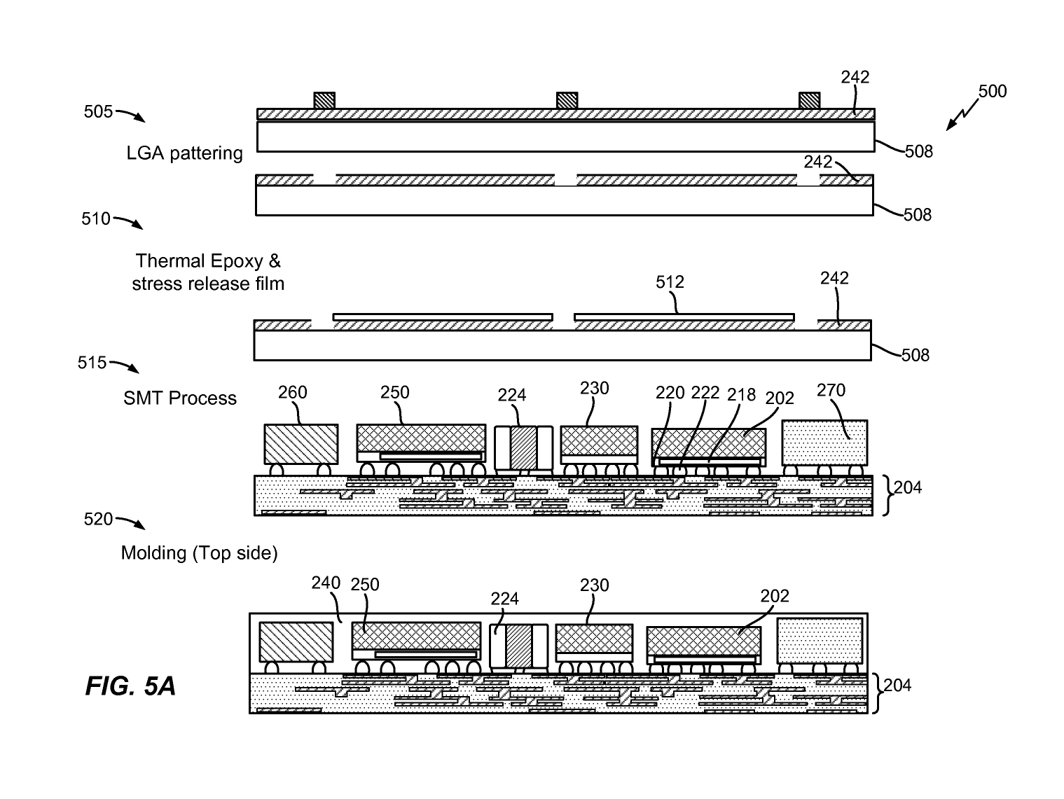

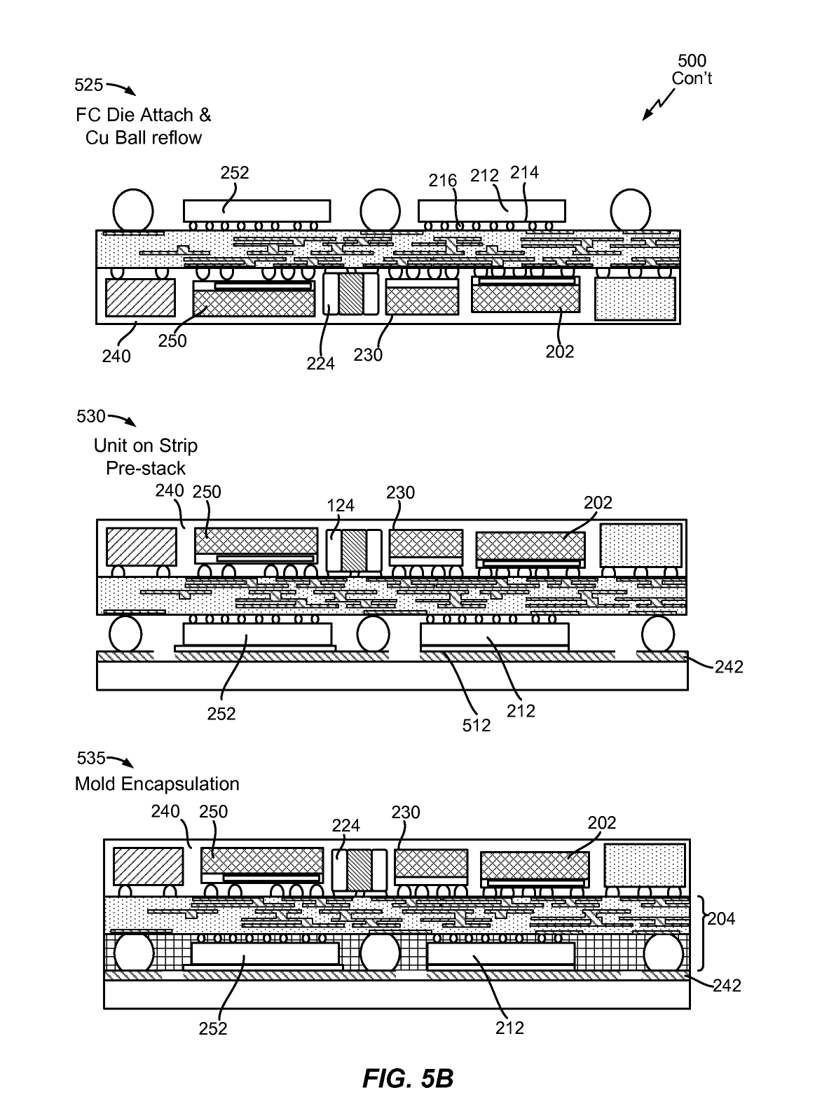

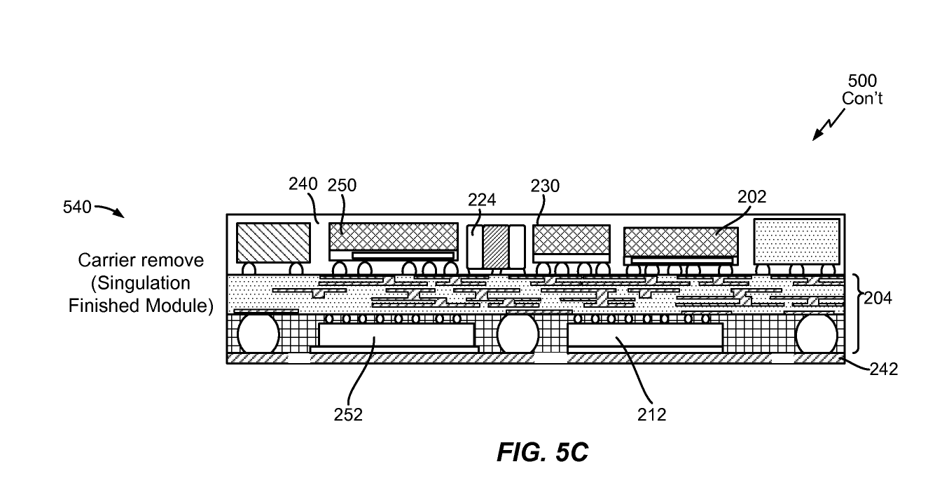

FIGS. 5A-C depict an exemplary method 500 for fabricating an integrated circuit package with a passive device. Deposition of a material to form at least a portion of a structure described herein can be performed using deposition techniques such as physical vapor deposition (PVD, e.g., sputtering), plasma-enhanced chemical vapor deposition (PECVD), thermal chemical vapor deposition (thermal CVD), and/or spin-coating. Etching of a material to form at least a portion of a structure described herein can be performed using etching techniques such as plasma etching, wet HF etching, etc. References in FIGS. 5A-C to elements in FIGS. 1-2 are provided as examples, and are not limiting.

In optional block 505, a layer of thermal epoxy is deposited on a carrier 508. The layer of thermal epoxy and may be patterned with a land grid array (LGA) pattern.

In optional block 510, a stress release film 512 is deposited on the layer of thermal epoxy. The stress release film 512 is also patterned with the LGA pattern. The carrier 508 is used again in block 530.

In block 515, at least one surface mount device (e.g., 270, 202, 230, 250, 260), including at least one integrated passive device (e.g., 202), is mounted on a first face of a substrate and electrically coupled redistribution layer (e.g., one or more metal layers) formed as part of a substrate 204. In an example, the substrate is a laminated substrate. The substrate can be coreless or have a core. The substrate can have at least one embedded metal layer as part of the redistribution layer, at least one layer that can distribute signals, ground and power. The mounting can include reflowing solder to adhere the surface mount device's electrical interconnects to respective electrical interconnects on the first face of the substrate.

In optional block 520, molding, underfill, or a combination thereof (e.g., 240) is applied adjacent to the surface mount devices.

In block 525, an active face of at least one integrated circuit (e.g. 212, 252) is attached to a second face of the substrate, in a flip-chip configuration. Thus, the at least one passive device is mounted in a face-to-face orientation with the at least one integrated circuit. Electrical interconnects (e.g., a pad, a contact, a solder ball, a solder pad, the like, or a combination thereof) are also attached to the second face of the substrate. The attaching can include reflowing solder to adhere the integrated circuit's electrical interconnects to respective electrical interconnects on the second face of the substrate. In another example, the attaching can include reflowing solder to adhere the electrical interconnects to respective electrical interconnects on the second face of the substrate. The electrical interconnects can be used to couple a metal layer (e.g., ground) in the substrate to ground on a circuit board to which the integrated circuit package is mounted.

In optional block 530, the at least one integrated circuit (e.g., 212, 252) is positioned on the stress release film 512.

In optional block 535, molding, underfill, or a combination thereof is applied adjacent to the at least one integrated circuit to encapsulate the at least one integrated circuit and the copper balls.

In optional block 540, the carrier 508 is removed from the layer of thermal epoxy. The integrated circuit package can also be singulated from other devices formed on the carrier 508.

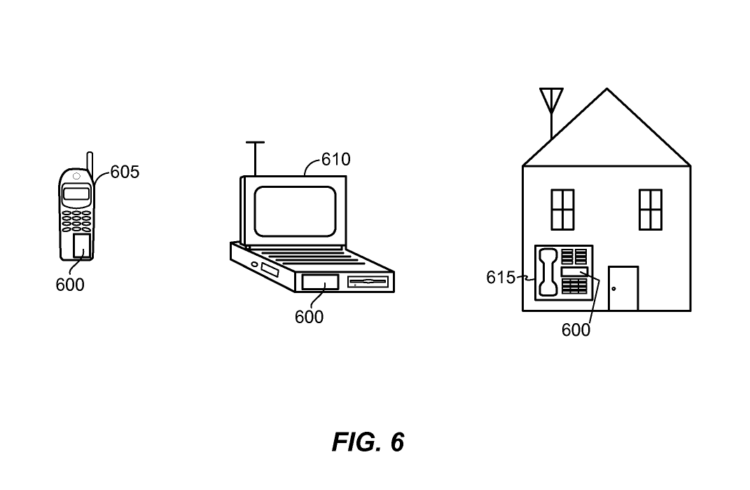

FIG. 6 illustrates various electronic devices that may be integrated with any of the aforementioned devices 600 (e.g., the IC package 100, the IC package 200). For example, any of a mobile phone device 605, a laptop computer device 610, and a fixed location terminal device 615 may include the device 600 as described herein. The devices 605, 610, 615 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, the like, or any practicable combination thereof.

One or more of the components, processes, features, and/or functions illustrated in FIGS. 1-6 may be rearranged and/or combined into a single component, process, feature or function or embodied in several components, processes, or functions. Additional elements, components, processes, and/or functions may also be added without departing from the disclosure. It should also be noted that FIGS. 1-6 and their corresponding description in the present disclosure is not limited to dies and/or ICs. In some implementations, FIGS. 1-6 and their corresponding description may be used to manufacture, create, provide, and/or produce integrated devices. In some implementations, a device may include a die, an integrated device, a die package, an integrated circuit, a device package, an integrated circuit package, a substrate, a semiconductor device, a package on package (PoP) device, and/or an interposer.

While this disclosure describes examples, changes and modifications can be made to the examples disclosed herein without departing from the scope defined by the appended claims. The present disclosure is not intended to be limited to the specifically disclosed examples alone.

What is claimed is:

1. An apparatus, comprising:
an integrated circuit having an active face, wherein the integrated circuit is embedded in a substrate;
an integrated passive device (IPD) having a face, wherein the active face of the integrated circuit faces the face of the IPD, and at least one contact of the IPD is arranged in an overlapping configuration relative to the integrated circuit; and
a redistribution layer (RDL) disposed between the IPD and the integrated circuit, wherein the RDL is configured to electrically couple the IPD and the integrated circuit.

2. The apparatus of claim 1, wherein the IPD includes at least one of a capacitor, an inductor, a transformer, a coil, or a combination thereof.

3. The apparatus of claim 1, further comprising:
a second integrated circuit embedded in the substrate; and
an interposer disposed between the integrated circuit and the second integrated circuit, the interposer electrically coupled to a first portion of the RDL and a second portion of the RDL, wherein the interposer is configured to couple signals between the integrated circuit and the IPD on the first portion of the RDL and the second circuit on the second portion of the RDL.

4. The apparatus of claim 3, wherein the interposer is embedded in the substrate or mounted external to the substrate.

5. The apparatus of claim 1, further comprising an electromagnetic shield located between the substrate and the IPD.

6. The apparatus of claim 5, wherein at least a portion of the RDL is configured as the electromagnetic shield.

7. The apparatus of claim 1, wherein the integrated circuit is coupled to a land grid array formed on the substrate.

8. The apparatus of claim 1, wherein the apparatus is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, a base station, and a device in a automotive vehicle, and further including the device.

9. A method for fabricating a package, comprising:
forming a redistribution layer (RDL) as part of a substrate;
mounting an integrated passive device (IPD) on the substrate and electrically coupling the IPD to a first side of the RDL; and
embedding an integrated circuit in the substrate in a face-to-face orientation with the IPD and electrically coupling the passive device to a second side of the RDL to electrically couple the IPD to the integrated circuit, wherein at least one contact of the IPD is arranged in an overlapping configuration relative to the integrated circuit.

10. The method of claim 9, wherein at least a portion of the RDL is configured as an electromagnetic shield.

11. The method of claim 9, wherein the IPD includes at least one of a capacitor, an inductor, a transformer, a coil, or a combination thereof.

12. The method of claim 9, further comprising
embedding a second integrated circuit in the substrate; and
embedding an interposer disposed between the integrated circuit and the second integrated circuit and electrically coupling the interposer to a first portion of the RDL and a second portion of the RDL, wherein the interposer is configured to couple signals between the integrated circuit and the IPD on the first portion of the RDL and the second circuit on the second portion of the RDL.

13. The method of claim 9, further comprising
embedding a second integrated circuit in the substrate; and
mounting an interposer on the substrate disposed between the integrated circuit and the second integrated circuit and electrically coupling the interposer to a first portion of the RDL and a second portion of the RDL, wherein the interposer is configured to couple signals between the integrated circuit and the IPD on a first portion of the RDL and the second circuit on a second portion of the RDL.

14. The method of claim 9, further comprising:
forming a land grid array (LGA) on the substrate; and
coupling the LGA to the integrated circuit.

15. The method of claim 9, further comprising incorporating the package into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, a base station, and a device in a automotive vehicle, and further including the device.

16. An apparatus, comprising:
an integrated circuit having an active face, wherein the integrated circuit is embedded in a substrate;
an integrated passive device (IPD) having a face, wherein the active face of the integrated circuit faces the face of the IPD, and at least one contact of the IPD is arranged in an overlapping configuration relative to the integrated circuit; and
means for electrically coupling the IPD to the integrated circuit, wherein means for electrically coupling is disposed between the IPD and the integrated circuit.

17. The apparatus of claim 16, wherein the IPD includes at least one of a capacitor, an inductor, a transformer, a coil, or a combination thereof.

18. The apparatus of claim 16, further comprising:
a second integrated circuit embedded in the substrate; and
an interposer disposed between the integrated circuit and the second integrated circuit, the interposer electrically coupled to a first portion of the means for electrically coupling and a second portion of the means for electrically coupling, wherein the interposer is configured to couple signals between the integrated circuit and the IPD on the first portion of the means for electrically coupling and the second circuit on the second portion of the means for electrically coupling.

19. The apparatus of claim 18, wherein the interposer is embedded in the substrate or mounted external to the substrate.

20. The apparatus of claim 16, further comprising an electromagnetic shield located between the substrate and the IPD.

21. The apparatus of claim 20, wherein at least a portion of the means for electrically coupling is configured as the electromagnetic shield.

22. The apparatus of claim 16, further comprising means for electrically coupling the integrated circuit to a land grid array, wherein the land grid array is formed on the substrate.

23. The apparatus of claim 16, wherein the apparatus is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, a base station, and a device in a automotive vehicle, and further including the device.
